(19) United States
(12) Patent Application Publication
(10) Pub. No.: US 2020/0303268 A1
(43) Pub. Date: Sep. 24, 2020

(54) SEMICONDUCTOR DEVICE INCLUDING RESIDUAL TEST PATTERN

(71) Applicant: SAMSUNG ELECTRONICS CO., LTD., Suwon-si, (KR)

(72) Inventor: Myoungsoo KIM, Hwaseong-si (KR)

(21) Appl. No.: 16/579,935

(22) Filed: Sep. 24, 2019

(30) Foreign Application Priority Data
Mar. 19, 2019 (KR) 10-2019-0030970

(51) Int. Cl. H01L 21/66; H01L 23/00; H01L 23/528; H01L 23/522; G01R 31/26

(52) U.S. Cl. CPC H01L 22/32; H01L 24/05; H01L 24/16; H01L 23/528; H01L 23/5226; H01L 24/03; H01L 21/78; H01L 2224/0557; H01L 2224/0401; H01L 2224/16257; H01L 2224/05571; H01L 24/94; H01L 2224/05624; G01R 31/2644

(57) ABSTRACT

A semiconductor device including a substrate including a bonding pad region and an edge region; and a residual test pattern on the edge region of the substrate, wherein a sidewall of the residual test pattern is aligned with a sidewall of the substrate.

### CROSS-REFERENCE TO RELATED APPLICATION

Korean Patent Application No. 10-2019-0030970, filed on Mar. 19, 2019, in the Korean Intellectual Property Office, and entitled: “Semiconductor Device Including Residual Test Pattern,” is incorporated by reference herein in its entirety.

### BACKGROUND

### 1. Field

Embodiments relate to a semiconductor device including a residual test pattern.

### 2. Description of the Related Art

A wafer on which semiconductor devices are formed may include chip regions on which the semiconductor devices are formed, and a scribe lane dividing the chip regions. Semiconductor components (e.g., transistors, resistors, and/or capacitors) constituting the semiconductor device may be formed on the chip region and may not be formed on the scribe lane. The wafer may be sawed along the scribe lane to complete or separate each of the semiconductor devices (or semiconductor chips). Test patterns for monitoring electrical characteristics and defective patterns of the semiconductor components on the chip region to inspect whether a process is normally performed may be on the scribe lane. Electrical characteristics of the test patterns may be measured to check whether processes are normally performed and/or characteristics of unit elements (e.g., transistors, a resistance of metal lines, and/or a resistance of vias) constituting the semiconductor components.

### SUMMARY

The embodiments may be realized by providing a semiconductor device including a substrate including a bonding pad region and an edge region; and a residual test pattern on the edge region of the substrate, wherein a sidewall of the residual test pattern is aligned with a sidewall of the substrate.

The embodiments may be realized by providing a semiconductor device including a substrate including a bonding pad region and an edge region; and a residual test pattern on the edge region of the substrate, wherein the residual test pattern includes protrusions protruding from a sidewall thereof when viewed in a plan view.

The embodiments may be realized by providing a semiconductor device including a substrate including a bonding pad region and an edge region; a residual test pattern structure on the edge region of the substrate; and a bonding pad on the bonding pad region, wherein the residual test pattern structure includes stacked residual test patterns, and an uppermost one of the residual test patterns includes a material that is different from a material of the bonding pad.

### BRIEF DESCRIPTION OF THE DRAWINGS

Features will be apparent to those of skill in the art by describing in detail exemplary embodiments with reference to the attached drawings in which:

FIG. 1 illustrates a plan view of a semiconductor device according to some embodiments.

FIG. 2 illustrates an enlarged view of a portion ‘P1’ of FIG. 1.

FIG. 3A illustrates a cross-sectional view taken along a line I-I′ of FIG. 2.

FIG. 3B illustrates a cross-sectional view taken along a line II-II′ of FIG. 2.

FIGS. 4A to 4C illustrate plan views of residual test patterns according to some embodiments.

FIG. 5 illustrates a cross-sectional view of a semiconductor device according to some embodiments.

FIG. 6 illustrates a plan view of a wafer in a process of manufacturing a semiconductor device according to some embodiments.

FIG. 7 illustrates an enlarged plan view of a portion ‘P2’ of FIG. 6, according to some embodiments.

FIGS. 8A to 8E illustrate cross-sectional views of stages in a method of manufacturing a semiconductor device having the cross section of FIG. 3A.

FIGS. 9 to 11 illustrate cross-sectional views of semiconductor devices according to some embodiments.

### DETAILED DESCRIPTION

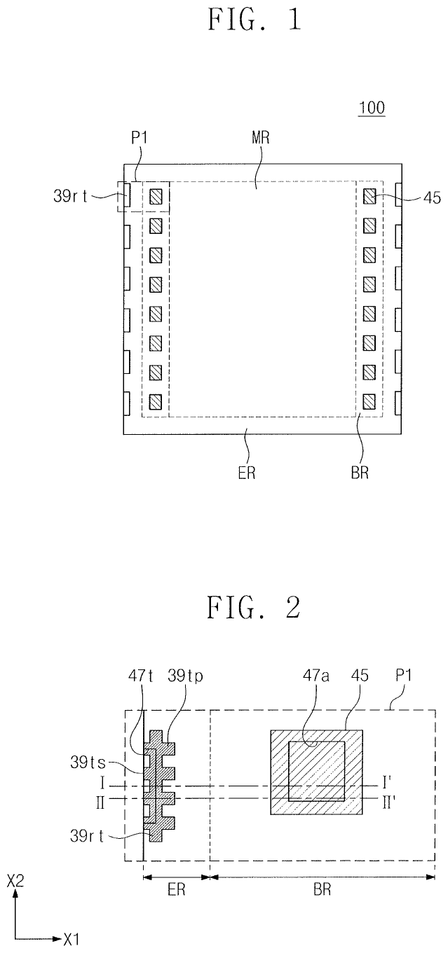

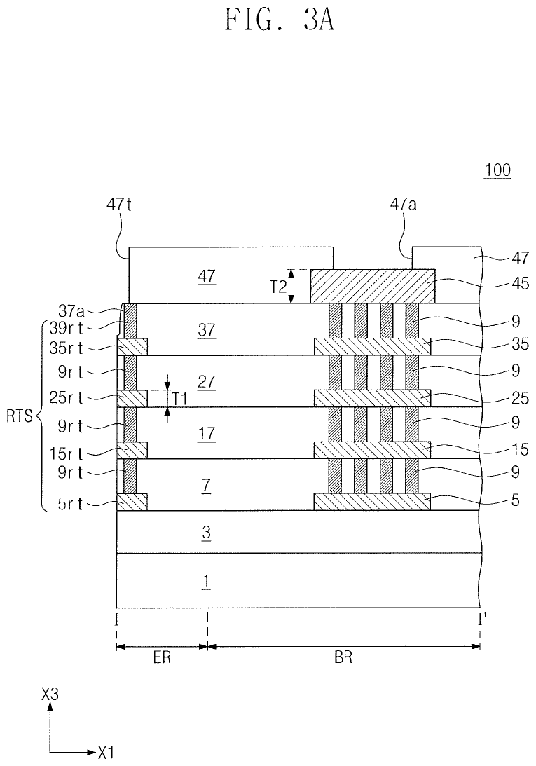

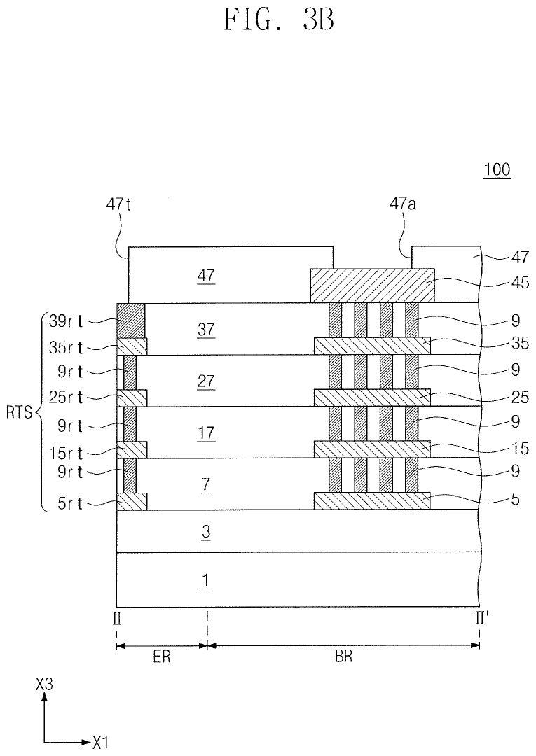

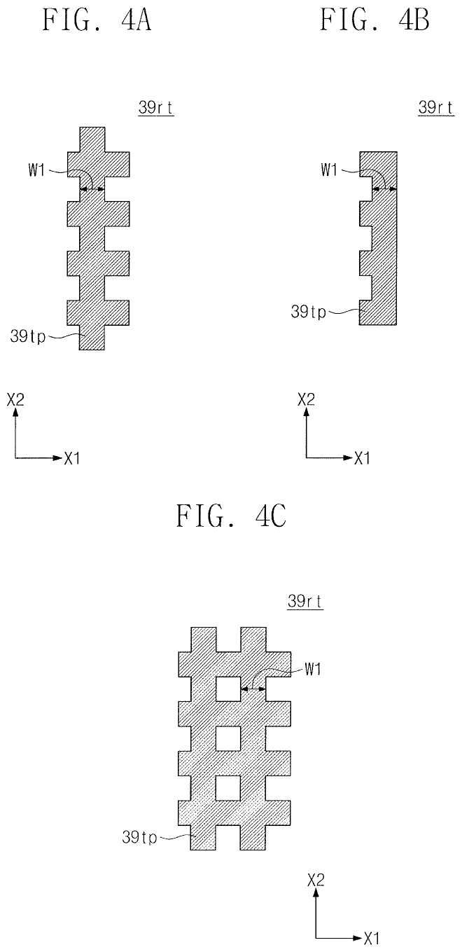

FIG. 1 illustrates a plan view of a semiconductor device according to some embodiments. FIG. 2 illustrates an enlarged view of a portion ‘P1’ of FIG. 1. FIG. 3A illustrates a cross-sectional view taken along a line I-I′ of FIG. 2. FIG. 3B illustrates a cross-sectional view taken along a line II-II′ of FIG. 2. FIGS. 4A to 4C illustrate plan views of residual test patterns according to some embodiments.

Referring to FIGS. 1, 2, 3A and 3B, a semiconductor device 100 according to the present embodiment may include a substrate 1. The substrate 1 may include a main chip region MR, a bonding pad region BR at an edge of the main chip region MR, and an edge region ER surrounding the main chip region MR and the bonding pad region BR. The main chip region MR may include, e.g., a cell array region, a peripheral circuit region, and a core circuit region. Bonding pads 45 may be on the bonding pad region BR. The bonding pads 45 may be electrically connected to circuits on the main chip region MR.

First to fifth interlayer insulating layers 3, 7, 17, 27 and 37 may be sequentially stacked on the substrate 1 (e.g., in a vertical or third direction X3). Each of the first to fifth interlayer insulating layers 3, 7, 17, 27 and 37 may include a single layer or a multi-layer, which may include, e.g., at least one of a silicon oxide layer, a silicon nitride layer, a silicon oxynitride layer, or a porous insulating layer.

A first interconnection line 5 and a first residual test pattern 5rt, which may be spaced apart from each other (e.g., in a first direction X1), may be between the first interlayer insulating layer 3 and the second interlayer insulating layer 7. A second interconnection line 15 and a second residual test pattern 15rt, which may be spaced apart from each other (e.g., in the first direction X1), may be between the second interlayer insulating layer 7 and the third interlayer insulating layer 17. A third interconnection line 25 and a third residual test pattern 25rt, which may be spaced apart from each other (e.g., in the first direction X1), may be between the third interlayer insulating layer 17 and the fourth interlayer insulating layer 27. A fourth interconnection line 35 and a fourth residual test pattern 35rt, which may be spaced apart from each other (e.g., in the first direction X1), may be between the fourth interlayer insulating layer 27 and the fifth interlayer insulating layer 37.

The first to fourth interconnection lines 5, 15, 25 and 35 may be on the bonding pad region BR. The bonding pad 45 may be on the fifth interlayer insulating layer 37 of the bonding pad region BR. Via plugs 9 (for connecting the interconnection lines 5, 15, 25 and 35 and the bonding pad 45) may be between the first to fourth interconnection lines 5, 15, 25 and 35 and between the fourth interconnection line 35 and the bonding pad 45.

The first to fourth residual test patterns 5rt, 15rt, 25rt and 35rt may be on the edge region ER. Each of the first to fourth residual test patterns 5rt, 15rt, 25rt and 35rt may have a plate shape or a mesh shape when viewed in a plan view. Residual test via plugs 9rt (for connecting the first to fourth residual test patterns 5rt, 15rt, 25rt and 35rt) may be between the first to fourth residual test patterns 5rt, 15rt, 25rt and 35rt. A fifth residual test pattern 39rt may be on the fourth residual test pattern 35rt. A passivation layer 47 may be on or cover (e.g., partially cover) the fifth residual test pattern 39rt, the bonding pad 45, and the fifth interlayer insulating layer 37. The passivation layer 47 may be formed of, e.g., a silicon nitride layer. The passivation layer 47 may include a first opening 47a exposing a portion of the bonding pad 45, and a second opening 47t exposing a portion of the fifth residual test pattern 39rt. The first to fifth residual test patterns 5rt, 15rt, 25rt, 35rt and 39rt and the residual test via plugs 9rt may constitute a residual test pattern structure RTS.

One of the first to fourth residual test patterns 5rt, 15rt, 25rt and 35rt and (e.g., a corresponding) one of the first to fourth interconnection lines 5, 15, 25 and 35, which are at the same height (or level, e.g., relative to the substrate 1 in the third direction X3), may include the same material and may the same thickness. For example, the first residual test pattern 5rt and the first interconnection line 5 may include the same material and may have the same thickness (e.g., in the third direction X3). In an implementation, the thickness of the fourth residual test pattern 35rt or the fourth interconnection line 35 may be equal to or greater than the thickness of the first residual test pattern 5rt or the first interconnection line 5.

In an implementation, the first to fourth residual test patterns 5rt, 15rt, 25rt and 35rt and the first to fourth interconnection lines 5, 15, 25 and 35 may include the same material and may have the same thickness (e.g., a first thickness T1). In an implementation, a thickness (e.g., a second thickness T2 in the third direction X3) of the bonding pad 45 may be greater than the thickness of each of the first to fourth residual test patterns 5rt, 15rt, 25rt and 35rt and the first to fourth interconnection lines 5, 15, 25 and 35.

The residual test via plugs 9rt and the fifth residual test pattern 39rt may include the same material. The fifth residual test pattern 39rt and an uppermost one of the via plugs 9 may have the same thickness (or vertical length, e.g., in the third direction X3).

In an implementation, as illustrated in FIG. 4A, the fifth residual test pattern 39rt may have a shape in which cross shapes are connected to each other along one direction (e.g., a second direction X2), when viewed in a plan view. In an implementation, the fifth residual test pattern 39rt may have a comb shape as illustrated in FIG. 4B or a mesh shape as illustrated in FIG. 4C, when viewed in a plan view. A width WI (e.g., in the first direction X1) of a narrowest portion of the fifth residual test pattern 39rt may be, e.g., 0.02 μm to 10 μm. In FIG. 2, the shape of FIG. 4A among the shapes of FIGS. 4A to 4C is illustrated as an example. A portion of a sidewall 39ts of the fifth residual test pattern 39rt may be aligned with a sidewall of the substrate 1 (e.g., a portion of the sidewall 39ts of the fifth residual test pattern 39rt may be coplanar with the sidewall of the substrate 1). Another portion of the sidewall of the fifth residual test pattern 39rt may be covered with an insulating spacer 37a. The insulating spacer 37a may include the same material as the fifth interlayer insulating layer 37.

A sidewall of at least one of the first to fourth residual test patterns 5rt, 15rt, 25rt and 35rt may be aligned with the sidewall of the substrate 1. The fifth residual test pattern 39rt may include a plurality of protrusions 39tp when viewed in a plan view. The protrusions 39tp of the fifth residual test pattern 39rt may help support an edge portion of the semiconductor device in a chip sawing process to help prevent the edge portion of the semiconductor device from collapsing. A top surface of the fifth residual test pattern 39rt (e.g., a surface facing away from the substrate 1) may be at the same height as or a lower height than a bottom surface of the bonding pad 45 (e.g., relative to the substrate 1, in the third direction X3).

In an implementation, the fifth residual test pattern 39rt may include a different material from that of the bonding pad 45. In an implementation, a ductility of the fifth residual test pattern 39rt may be less than a ductility of the bonding pad 45. In an implementation, a hardness of the fifth residual test pattern 39rt may be greater than a hardness of the bonding pad 45. In an implementation, the fifth residual test pattern 39rt may include, e.g., tungsten. In an implementation, the bonding pad 45 may include, e.g., aluminum. The first to fourth residual test patterns 5rt, 15rt, 25rt and 35rt and the first to fourth interconnection lines 5, 15, 25 and 35 may include, e.g., aluminum. The via plugs 9 and the residual test via plugs 9rt may include, e.g., tungsten.

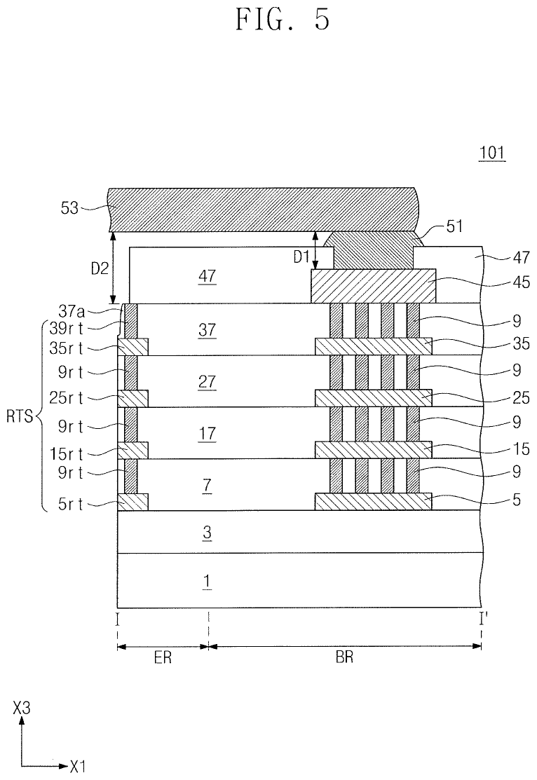

FIG. 5 illustrates a cross-sectional view of a semiconductor device according to some embodiments of the inventive concepts.

Referring to FIG. 5, a bump 51 may be on a bonding pad 45 in a semiconductor device according to the present embodiment. The bump 51 may have a single-layered or a multi-layered structure including, e.g., at least one of copper, tin, or lead. A lead frame 53 may be adhered onto or coupled with the bump 51. The lead frame 53 may include, e.g., at least one of copper, gold, tin, or lead. In FIG. 5, a first distance D1 (e.g., in the third direction X3) from the lead frame 53 to the bonding pad 45 may be less than a second distance D2 (e.g., in the third direction X3) from the lead frame 53 to the fifth residual test pattern 39rt.

In the semiconductor devices 100 and 101 according to the embodiments, the fifth residual test pattern 39rt located at an uppermost position on the edge region ER may have the ductility and/or the hardness of the conditions described above, and a metal burr phenomenon may not occur in a sawing process. For example, it is possible to prevent the fifth residual test pattern 39rt from being in contact with or shorted to a conductive pattern (e.g., the lead frame 53) adjacent thereto. In addition, the fifth residual test pattern 39rt may be lower than the bonding pad 45 to help prevent the fifth residual test pattern 39rt from being in contact with or shorted to a conductive pattern (e.g., the lead frame 53) adjacent thereto.

In an implementation, the semiconductor device may be a display driver integrated circuit (display driver IC; DDI). The display driver IC may include a greater number of input/output (I/O) pads as compared with other semiconductor devices, and distances between the I/O pads of the display driver IC may be very small. If the metal burr phenomenon were to occur at a residual test pattern of the display driver IC, the possibility of occurrence of a short could greatly increase. In an implementation, the display driver IC may have the aforementioned structure according to the embodiments, and the metal burr phenomenon may be prevented, to help improve the reliability of the semiconductor device (e.g., the display driver IC).

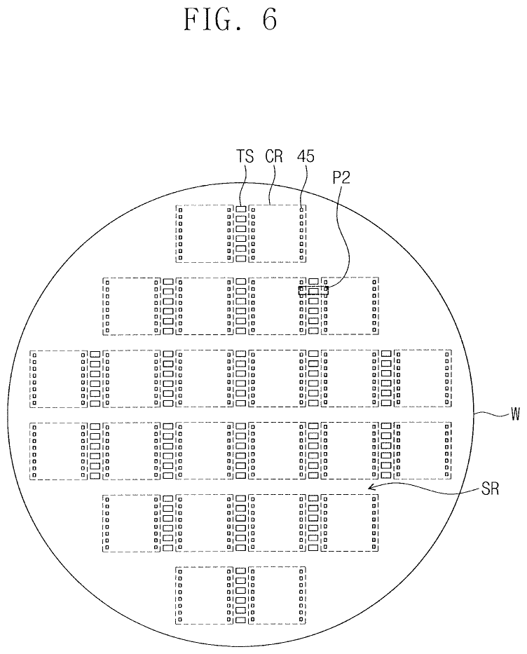

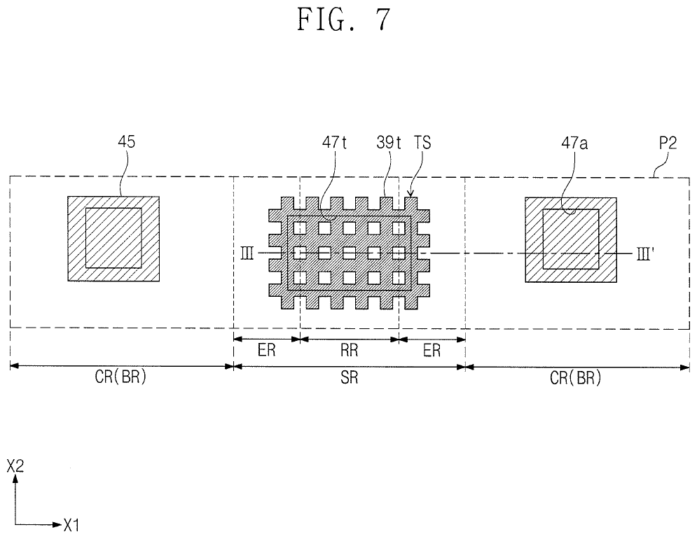

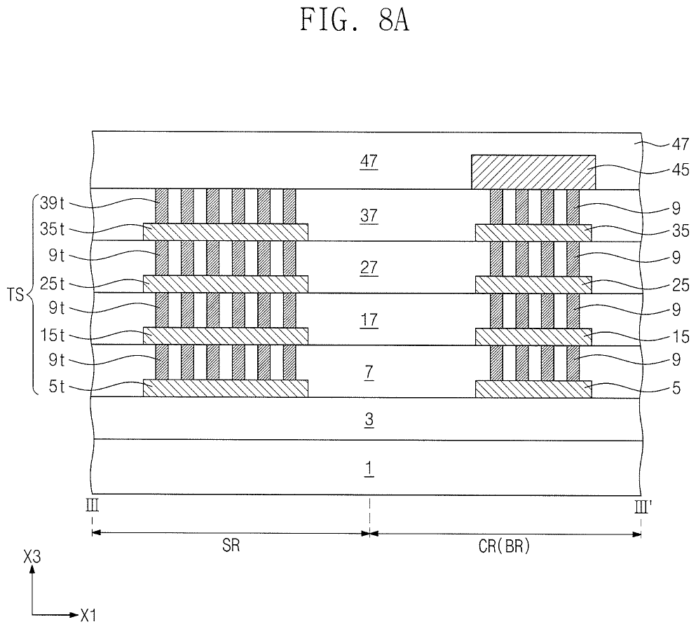

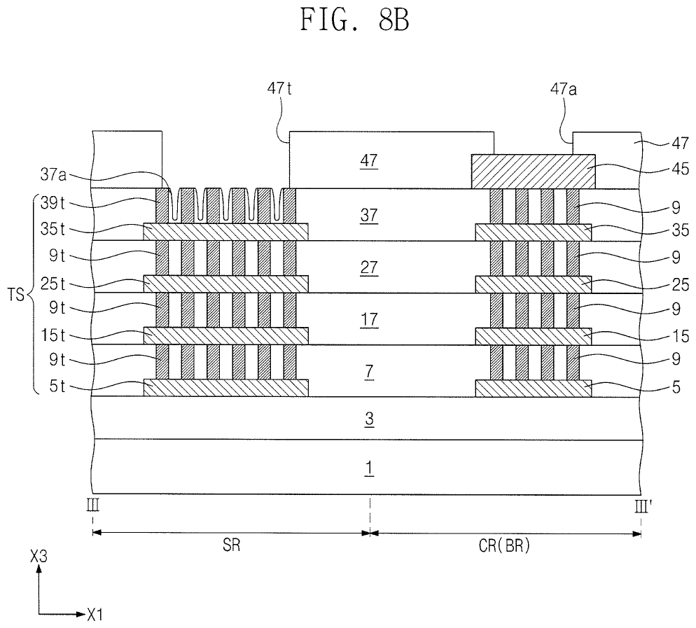

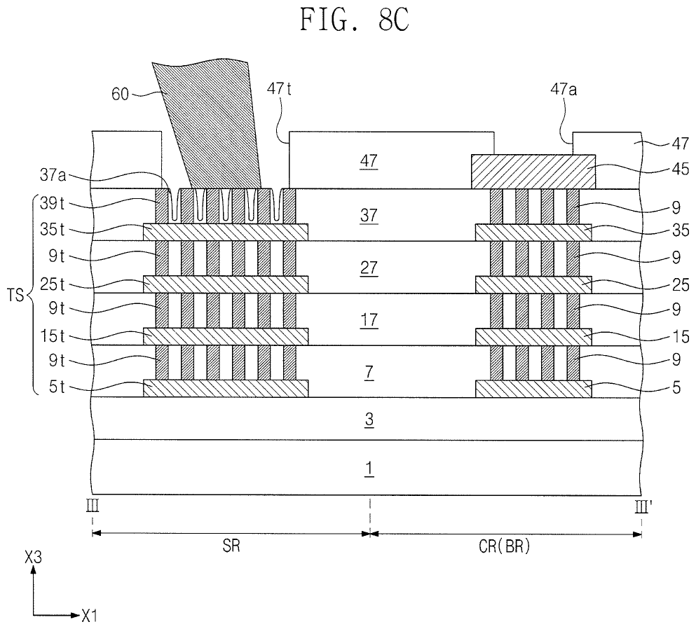

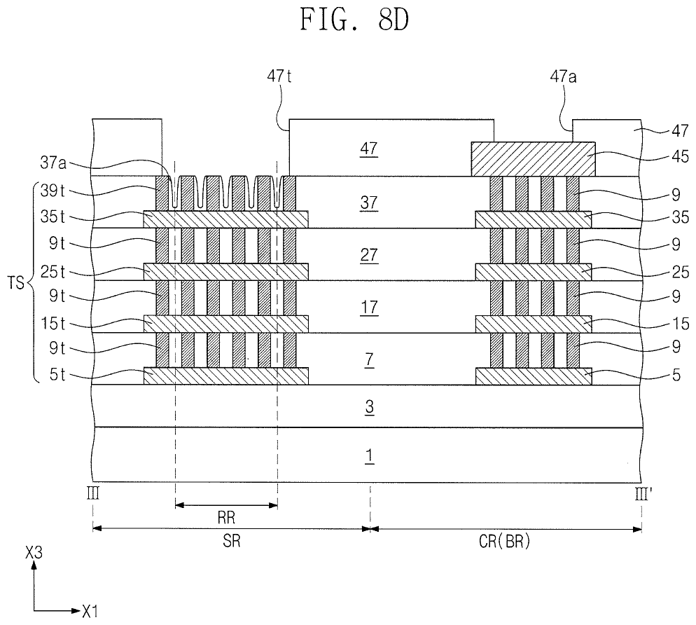

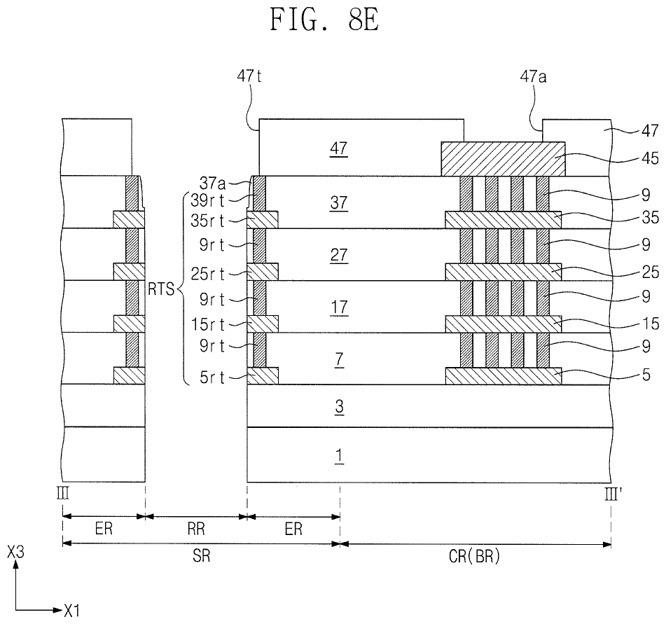

FIG. 6 illustrates a plan view of a wafer in a process of manufacturing a semiconductor device according to some embodiments. FIG. 7 illustrates an enlarged plan view of a portion ‘P2’ of FIG. 6, according to some embodiments. FIGS. 8A to 8E illustrate cross-sectional views of stages in a method of manufacturing a semiconductor device having the cross section of FIG. 3A.

Referring to FIG. 6, a plurality of chip regions CR may be arranged in or on a wafer W. The main chip region MR and the bonding pad regions BR of FIG. 1 may be in each of the chip regions CR. A scribe lane region SR may be between the chip regions CR. A plurality of test pattern structures TS may be on the scribe lane region SR. Some of the test pattern structures TS may be connected to each other. The test pattern structures TS may be insulated from circuits on the chip regions CR.

Referring to FIGS. 7 and 8A, the wafer W may correspond to the substrate 1. The first to fifth interlayer insulating layers 3, 7, 17, 27 and 37 may be on the substrate 1, as described with reference to FIGS. 3A and 3B. The first to fourth interconnection lines 5, 15, 25 and 35, the via plugs 9 and the bonding pad 45 may be on each of the bonding pad regions BR of the chip regions CR of the wafer W. The test pattern structure TS may be on the scribe lane region SR of the wafer W. The test pattern structure TS may include first to fifth test patterns 5t, 15t, 25t, 35t and 39t sequentially stacked, and test via plugs 9t connecting the first to fifth test patterns 5t, 15t, 25t, 35t and 39t. The fifth test pattern 39t may have a mesh shape as illustrated in FIG. 7. A passivation layer 47 may cover the fifth test pattern 39t, the bonding pad 45, and the fifth interlayer insulating layer 37.

Referring to FIGS. 7 and 8B, the passivation layer 47 may be patterned to form a first opening 47a exposing the bonding pad 45 and a second opening 47t exposing the fifth test pattern 39t. At this time, portions of the fifth interlayer insulating layer 37 located in the mesh structure of the fifth test pattern 39t may also be etched to form an insulating spacer 37a.

Referring to FIGS. 7 and 8C, a test process may be performed. For example, a probe needle 60 of a probe card may come in contact with a surface of the fifth test pattern 39t (exposed through the second opening 47t) and test signals may be applied through the probe needle 60, thereby performing the test process. Electrical characteristics of semiconductor components may be measured by the test process to check whether each manufacturing process is normally performed, and/or to check characteristics of a unit element (e.g., characteristics of a transistor, a resistance of a metal line, and/or a resistance of a via). At this time, the fifth test pattern 39t may have the mesh shape, and contact reliability may be improved. For example, the test process may be smoothly performed, even if the probe needle 60 were to contact only a portion of the fifth test pattern 39t.

Referring to FIGS. 7, 81) and 8E, a chip sawing process using a blade may be performed to separate the chip regions CR from each other. At this time, a removal region RR of the scribe lane region SR may be removed by the blade. For example, an edge region ER (corresponding to a portion of the scribe lane region SR) may remain at an edge of the chip region CR. In addition, by the chip sawing process, a central portion of the test pattern structure TS may be removed, but an edge portion of the test pattern structure TS may remain. For example, the residual test pattern structure RTS described with reference to FIG. 3A may remain. The fifth residual test pattern 39rt of the residual test pattern structure RST may have one of the planar shapes of FIGS. 4A to 4C, depending on a degree of the removal of the test pattern structure TS. The semiconductor device 100 of FIG. 1 may be manufactured through the above processes. Subsequently, a packaging process may be performed to form the bump 51 and/or the lead frame 53 described with reference to FIG. 5.

In an implementation, the fifth test pattern 39t may have the mesh shape as a result of the chip sawing process, the amount of metal in the fifth test pattern 39t may be relatively reduced, and occurrence of metallic particles may be reduced. As a result, the chip sawing process may be smoothly performed. In addition, the fifth test pattern 39t may include a material that has a smaller ductility and a greater hardness than those of the bonding pad 45, and a metal burr phenomenon of the fifth test pattern 39t may not occur even though the fifth test pattern 39t is cut in the chip sawing process. As a result, contact between the fifth residual test pattern 39rt and an adjacent conductive pattern may be prevented.

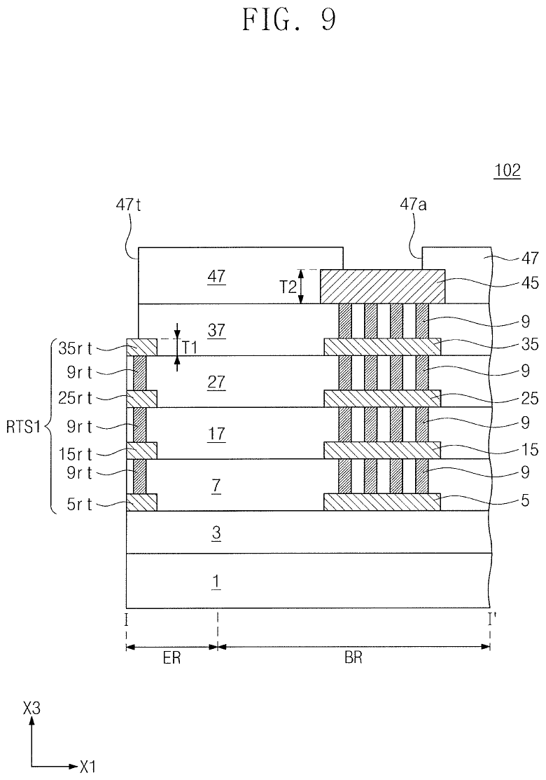

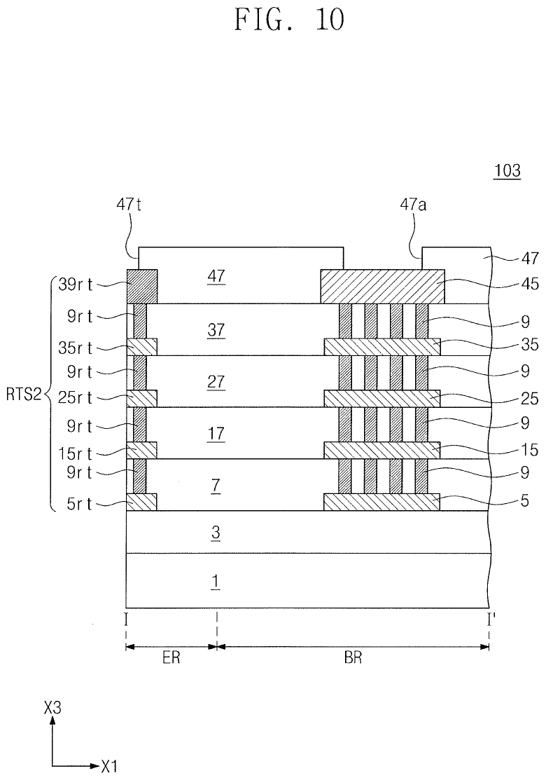

FIGS. 9 to 11 illustrate cross-sectional views of semiconductor devices according to some embodiments.

Referring to FIG. 9, in a semiconductor device 102 according to the present embodiment, a residual test pattern structure RTS1 may not include the fifth residual test pattern (39rt of FIG. 3A). A fourth residual test pattern 35rt (located at an uppermost position in the residual test pattern structure RTS1) may include the same material as a bonding pad 45, and may be located at a lower position than the bonding pad 45 (e.g., a distance from the substrate 1 to the fourth residual test pattern 35rt in the third direction X3 may be less than a distance from the substrate 1 to the bonding pad 45 in the third direction X3). A second opening 47t of the passivation layer 47 may be transferred or extend into the fifth interlayer insulating layer 37 to expose a top surface of the fourth residual test pattern 35rt. The fourth residual test pattern 35rt may be located at the same height as a fourth interconnection line 35. A thickness T1 of the fourth residual test pattern 35rt (e.g., in the third direction X3) may be less than a thickness T2 of the bonding pad 45 (e.g., in the third direction X3). For example, even if a metal burr phenomenon were to occur at the fourth residual test pattern 35rt when the semiconductor device 102 of FIG. 9 is manufactured, a degree of the metal burr phenomenon may be small and thus may not affect reliability of the semiconductor device. In the semiconductor device 102 of FIG. 9, the fifth residual test pattern 39rt may be excluded from the residual test pattern structure RTS1. In an implementation, the fourth residual test pattern 35rt (and the third residual test pattern 25rt) may also be excluded from the residual test pattern structure. Other components and structures and a manufacturing process of the semiconductor device 102 may be the same/similar as described above.

Referring to FIG. 10, in a semiconductor device 103 according to the present embodiment, a residual test pattern structure RTS2 may include a fifth residual test pattern 39rt. Here, a height (or level) and a thickness of the fifth residual test pattern 39rt may be the same as those of the bonding pad 45. The fifth residual test pattern 39rt may be spaced apart from the fourth residual test pattern 35rt (e.g., in the third direction X3). The fifth residual test pattern 39rt may be electrically connected to the fourth residual test pattern 35rt through a residual test via plug 9rt. In an implementation, a material of the fifth residual test pattern 39rt may be different from that of the bonding pad 45. In an implementation, a ductility of the fifth residual test pattern 39rt may be less than a ductility of the bonding pad 45. In an implementation, a hardness of the fifth residual test pattern 39rt may be greater than a hardness of the bonding pad 45. For example, the possibility of occurrence of a metal burr phenomenon of the fifth residual test pattern 39rt may be reduced. Other components and structures and a manufacturing process of the semiconductor device 103 may be the same/similar as described above.

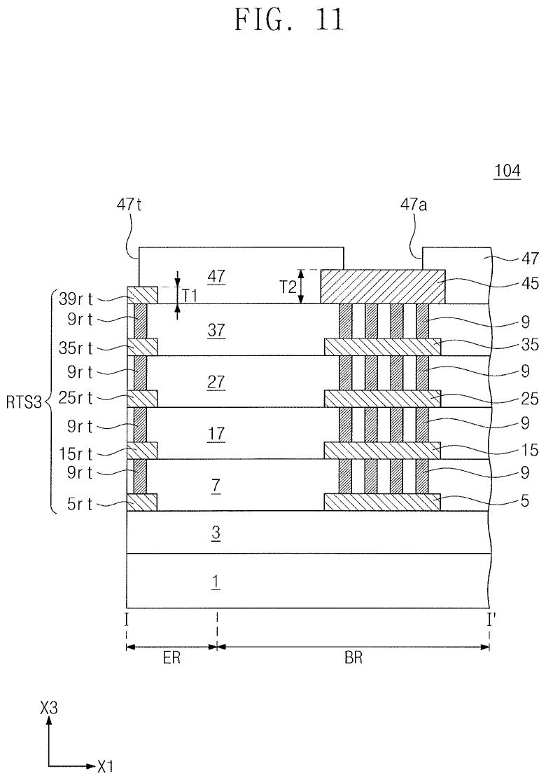

Referring to FIG. 11, in a semiconductor device 104 according to the present embodiment, a residual test pattern structure RTS3 may include a fifth residual test pattern 39rt. Here, a height (or level, e.g., of substrate 1-facing surfaces) and a material of the fifth residual test pattern 39rt may be the same as those of the bonding pad 45. A thickness T1 (e.g., in the third direction X3) of the fifth residual test pattern 39rt may be less than a thickness T2 (e.g., in the third direction X3) of the bonding pad 45. For example, the possibility of occurrence of a metal burr phenomenon of the fifth residual test pattern 39rt may be reduced. Other components and structures and a manufacturing process of the semiconductor device 104 may be the same/similar as described with reference to FIG. 10.

The semiconductor device according to the embodiments may help prevent a metal burr phenomenon from occurring at the residual test pattern, and a short may be prevented and the reliability of the semiconductor device may be improved.

One or more embodiments may provide a semiconductor device capable of preventing a short between a residual test pattern and a conductive pattern adjacent thereto.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a bonding pad region and an edge region; and
a residual test pattern on the edge region of the substrate,
wherein a sidewall of the residual test pattern is aligned with a sidewall of the substrate.

2. The semiconductor device as claimed in claim 1, wherein the residual test pattern has a comb shape, a mesh shape, or a shape in which cross shapes are connected to each other along one direction, when viewed in a plan view.

3. The semiconductor device as claimed in claim 1, further comprising a bonding pad on the bonding pad region of the substrate,
wherein a ductility of the residual test pattern is less than a ductility of the bonding pad.

4. The semiconductor device as claimed in claim 1, further comprising a bonding pad on the bonding pad region of the substrate,
wherein a hardness of the residual test pattern is greater than a hardness of the bonding pad.

5. The semiconductor device as claimed in claim 1, further comprising a bonding pad on the bonding pad region of the substrate,
wherein a thickness of the residual test pattern in a vertical direction is less than a thickness of the bonding pad in the vertical direction.

6. The semiconductor device as claimed in claim 1, further comprising a bonding pad on the bonding pad region of the substrate,
wherein a height of a top surface of the residual test pattern relative to the substrate in a vertical direction is the same as or lower than a height of a bottom surface of the bonding pad relative to the substrate in the vertical direction.

7. The semiconductor device as claimed in claim 1, further comprising an insulating spacer covering a sidewall of the residual test pattern.

8. The semiconductor device as claimed in claim 1, further comprising:
a bonding pad on the bonding pad region of the substrate; and
a lead frame connected to the bonding pad,
wherein a distance from the residual test pattern to the lead frame is greater than a distance from the bonding pad to the lead frame.

9. A semiconductor device, comprising:
a substrate including a bonding pad region and an edge region; and
a residual test pattern on the edge region of the substrate,
wherein the residual test pattern includes protrusions protruding from a sidewall thereof when viewed in a plan view.

10. The semiconductor device as claimed in claim 9, wherein a sidewall of at least one of the protrusions is aligned with a sidewall of the substrate.

11. The semiconductor device as claimed in claim 9, further comprising a bonding pad on the bonding pad region of the substrate,
wherein a ductility of the residual test pattern is less than a ductility of the bonding pad.

12. The semiconductor device as claimed in claim 9, further comprising a bonding pad on the bonding pad region of the substrate,
wherein a hardness of the residual test pattern is greater than a hardness of the bonding pad.

13. The semiconductor device as claimed in claim 9, further comprising a bonding pad on the bonding pad region of the substrate,
wherein a thickness of the residual test pattern in a vertical direction is less than a thickness of the bonding pad in the vertical direction.

14. The semiconductor device as claimed in claim 9, further comprising a bonding pad on the bonding pad region of the substrate,
wherein a height of the residual test pattern relative to the substrate in a vertical direction is the same as or lower than a height of the bonding pad relative to the substrate in the vertical direction.

15. A semiconductor device, comprising:
a substrate including a bonding pad region and an edge region;
a residual test pattern structure on the edge region of the substrate; and
a bonding pad on the bonding pad region,
wherein:
the residual test pattern structure includes stacked residual test patterns, and
an uppermost one of the residual test patterns includes a material that is different from a material of the bonding pad.

16. The semiconductor device as claimed in claim 15, wherein a sidewall of at least one of the residual test patterns is aligned with a sidewall of the substrate.

17. The semiconductor device as claimed in claim 15, wherein a ductility of the uppermost one of the residual test patterns is less than a ductility of the bonding pad.

18. The semiconductor device as claimed in claim 15, wherein a hardness of the uppermost one of the residual test patterns is greater than a hardness of the bonding pad.

19. The semiconductor device as claimed in claim 15, wherein a thickness of the uppermost one of the residual test patterns in a vertical direction is less than a thickness of the bonding pad in the vertical direction.

20. The semiconductor device as claimed in claim 15, wherein a height of the uppermost one of the residual test patterns relative to the substrate in a vertical direction is the same as or lower than a height of the bonding pad relative to the substrate in the vertical direction.
